(19) United States
(12) Patent Application Publication
(10) Pub. No.: US 2026/0096359 A1
(43) Pub. Date: Apr. 2, 2026

(54) PRECURSOR FOR FORMING LANTHANIDE METAL-CONTAINING THIN FILM, METHOD FOR FORMING LANTHANIDE METAL-CONTAINING THIN FILM USING SAME, AND SEMICONDUCTOR DEVICE COMPRISING LANTHANIDE METAL-CONTAINING THIN FILM

(71) Applicant: SK TRI CHEM CO., LTD., Sejong (KR)

(72) Inventors: Han Byul KIM, Sejong (KR); Han Sol OH, Sejong (KR); Yong Joo PARK, Sejong (KR); Beom Seok RYU, Sejong (KR); Dong Hyun KIM, Sejong (KR); Sang Kyung LEE, Sejong (KR)

(21) Appl. No.: 19/412,823

(22) Filed: Dec. 8, 2025

Related U.S. Application Data
(63) Continuation of application No. PCT/KR2024/096456, filed on Nov. 1, 2024.

(30) Foreign Application Priority Data
Nov. 29, 2023 (KR) 10-2023-0169126

(51) Int. Cl. H10P 14/40; C07F 5/00; C23C 16/50

(52) U.S. Cl. CPC H10P 14/412; C07F 5/003; C23C 16/50

(57) ABSTRACT

Proposed are a precursor for forming a lanthanide metal-containing thin film, the precursor including a compound represented by Chemical Formula 1, a method for forming a lanthanide metal-containing thin film using the same, and a semiconductor device including the lanthanide metal-containing thin film. The precursor for forming the thin film contains an amidinate ligand and thus exhibits chemical properties, such as high heat resistance and high volatility, thereby enabling the formation of a high-quality thin film.

### TECHNICAL FIELD

The present disclosure relates to a precursor for forming a lanthanide metal-containing thin film, a method for forming a lanthanide metal-containing thin film using the same, and a semiconductor device including the lanthanide metal-containing thin film. More particularly, the present disclosure relates to a precursor for forming a lanthanide metal-containing thin film, the precursor being capable of forming a high-quality thin film by constructing a precursor having high heat resistance and high volatility through a chemical structure containing an amidinate ligand, to a method for forming a thin film using the same, and to a semiconductor device including the thin film.

### BACKGROUND ART

With improved integration density achieved through the miniaturization of line widths of semiconductor devices, the space allowed for implementing capacitor structures has become limited. Accordingly, there have been limitations in using existing silicon-based dielectrics in manufacturing methods for semiconductor devices designed to implement capacitor structures. Additionally, with the application of high-dielectric thin films to replace silicon-based dielectrics, there have been issues where the leakage current caused by the band gap of such high-dielectric materials is significantly increased, resulting in degradation. One of the solutions for addressing these issues requires a technology for forming high-quality thin films, which necessitates the optimization of precursors used in thin film formation for that purpose.

To this end, various lanthanide metal-containing precursors are being developed. For example, Korean Patent Application Publication No. 10-2019-0008427 has disclosed a lanthanide metal-containing precursor containing an aza-allyl ligand, and Korean Patent Application Publication No. 10-2019-0094238 has disclosed a lanthanide metal-containing precursor containing a cyclopentadienyl ligand.

In particular, complex compounds containing cyclopentadienyl groups have lower melting points and higher volatility than compounds containing beta-diketonate or bis(trimethylsilyl)amide and, therefore, are advantageous for use as precursors in thin-film formation processes.

For these reasons, known technologies, including Korean Patent No. 10-1660052, Korean Patent Application Publication No. 10-2019-0109142, and Korean Patent Application Publication No. 10-2021-0084297, in the art have proposed chemical structures serving as lanthanide metal-containing precursors, to which cyclopentadienyl and amidinate are bound as ligands. It has been reported that the precursors to which these ligands are bound can overcome the disadvantages of existing lanthanide metal precursors having low vapor pressure and high viscosity, and thus are suitable for use in thin-film formation processes.

Such technologies have led to the expectation that the chemical properties of precursors can be enhanced by applying amidinate ligands to metal-containing precursor compounds.

### DISCLOSURE

### Technical Problem

The present disclosure, which has been devised in view of technologies in the art as described above, aims to provide a novel precursor for forming a lanthanide metal-containing thin film, the precursor being capable of exhibiting suitable chemical properties for use as a precursor for thin film formation.

The present disclosure also aims to provide a precursor for forming a lanthanide metal-containing thin film, the precursor exhibiting chemical properties, such as high heat resistance and high volatility.

The present disclosure also aims to provide a method for forming a thin film using the above precursor.

The present disclosure also aims to provide a semiconductor device including the above thin film.

### Technical Solution

A precursor for forming a lanthanide metal-containing thin film of the present disclosure, which is provided to achieve the objectives as described above, is characterized by including a compound represented by Chemical Formula 1 below.

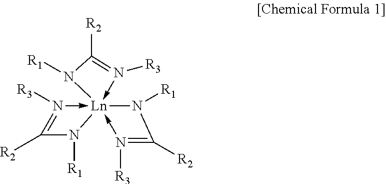

In Chemical Formula 1, Ln refers to a lanthanide metal, R₁ and R₃ are each independently a straight-chain, branched-chain, or cyclic alkyl or alkenyl group having 1 to 5 carbon atoms, and R₂ is a hydrogen atom, or a straight-chain, branched-chain, or cyclic alkyl or alkenyl group having 1 to 8 carbon atoms.

Additionally, in Chemical Formula 1, R₂ may be a hydrogen atom, or a straight-chain, branched-chain, or cyclic alkyl or alkenyl group having 1 to 4 carbon atoms.

Additionally, in Chemical Formula 1, R₁ and R₃ may each independently be a straight-chain, branched-chain, or cyclic alkyl or alkenyl group having 2 to 5 carbon atoms.

Additionally, in Chemical Formula 1, R₁ and R₃ may be ethyl groups.

Additionally, in Chemical Formula 1, R₂ may be an n-propyl group.

Additionally, in Chemical Formula 1, R₁ and R₃ may each independently be a straight-chain alkyl or alkenyl group having 1 to 5 carbon atoms.

Additionally, in Chemical Formula 1, R₂ may be a straight-chain alkyl or alkenyl group having 1 to 8 carbon atoms.

Additionally, in Chemical Formula 1, R₁ and R₃ may both be the same, and may be straight-chain, branched-chain, or cyclic alkyl or alkenyl groups having 1 to 5 carbon atoms.

Additionally, the precursor for forming the lanthanide metal-containing thin film may be liquid at room temperature.

Additionally, the precursor for forming the thin film may further include a solvent, which may include one or more of the following: a saturated or unsaturated hydrocarbon having 1 to 16 carbon atoms, a ketone, an ether, glyme, an ester, tetrahydrofuran (THF), and a tertiary amine. Additionally, the solvent may be included in an amount in a range of 1 to 99 wt % with respect to the total weight of the precursor for forming the thin film.

Additionally, examples of the compound represented by Chemical Formula 1 may include the following compounds:
Ln(Me₂,H-AMD) 3, Ln(Me₂,Me-AMD)₃, Ln(Me₂,Et-AMD)₃, Ln(Me₂,nPr-AMD)₃, Ln(Me₂,iPr-AMD)₃, Ln(Me₂,nBu-AMD)₃, Ln(Me₂,isoBu-AMD)₃, Ln(Me₂,secBu-AMD)₃, Ln(Me₂,tertBu-AMD)₃, Ln(Me₂,n-pentyl-AMD)₃, Ln(Me₂,sec-pentyl-AMD)₃, Ln(Me₂,cyclopentyl-AMD)₃, Ln(Me₂,n-hexyl-AMD)₃, Ln(Et,Me,H-AMD)₃, Ln(Et,Me,Me-AMD)₃, Ln(Et,Me,Et-AMD)₃, Ln(Et,Me,nPr-AMD)₃, Ln(Et,Me,iPr-AMD)₃, Ln(Et,Me,nBu-AMD)₃, Ln(Et,Me,isoBu-AMD)₃, Ln(Et,Me,secBu-AMD)₃, Ln(Et,Me,tertBu-AMD)₃, Ln(Et,Me,n-pentyl-AMD)₃, Ln(Et,Me,sec-pentyl-AMD)₃, Ln(Et,Me,cyclopentyl-AMD)₃, Ln(Et,Me,n-hexyl-AMD)₃, Ln(Et₂,H-AMD)₃, Ln(Et₂,Me-AMD)₃, Ln(Et₂,Et-AMD)₃, Ln(Et₂,nPr-AMD)₃, Ln(Et₂,iPr-AMD)₃, Ln(Et₂,nBu-AMD)₃, Ln(Et₂,isoBu-AMD)₃, Ln(Et₂,secBu-AMD)₃, Ln(Et₂,tertBu-AMD)₃, Ln(Et₂,n-pentyl-AMD)₃, Ln(Et₂,sec-pentyl-AMD)₃, Ln(Et₂,cyclopentyl-AMD)₃, Ln(Et₂,n-hexyl-AMD)₃, Ln(Et,nPr,H-AMD)₃, Ln(Et,nPr,Me-AMD)₃, Ln(Et,nPr,Et-AMD)₃, Ln(Et,nPr,nPr-AMD)₃, Ln(Et,nPr,iPr-AMD)₃, Ln(Et,nPr,nBu-AMD)₃, Ln(Et,nPr,isoBu-AMD)₃, Ln(Et,nPr,secBu-AMD)₃, Ln(Et,nPr,tertBu-AMD)₃, Ln(Et,nPr,n-pentyl-AMD)₃, Ln(Et,nPr,sec-pentyl-AMD)₃, Ln(Et,nPr,cyclopentyl-AMD)₃, Ln(Et,nPr,n-hexyl-AMD)₃, Ln(nPr,Me,H-AMD)₃, Ln(nPr,Me,Me-AMD)₃, Ln(nPr,Me,Et-AMD)₃, Ln(nPr,Me,nPr-AMD)₃, Ln(nPr,Me,iPr-AMD)₃, Ln(nPr,Me,nBu-AMD)₃, Ln(nPr,Me,isoBu-AMD)₃, Ln(nPr,Me,secBu-AMD)₃, Ln(nPr,Me,tertBu-AMD)₃, Ln(nPr,Me,n-pentyl-AMD)₃, Ln(nPr,Me,sec-pentyl-AMD)₃, Ln(nPr,Me,cyclopentyl-AMD)₃, Ln(nPr,Me,n-hexyl-AMD)₃, Ln(nPr₂,H-AMD)₃, Ln(nPr₂,Me-AMD)₃, Ln(nPr₂,Et-AMD)₃, Ln(nPr₂,nPr-AMD)₃, Ln(nPr₂,iPr-AMD)₃, Ln(nPr₂,nBu-AMD)₃, Ln(nPr₂,isoBu-AMD)₃, Ln(nPr₂,secBu-AMD)₃, Ln(nPr₂,tertBu-AMD)₃, Ln(nPr₂,n-pentyl-AMD)₃, Ln(nPr₂,sec-pentyl-AMD)₃, Ln(nPr₂,cyclopentyl-AMD)₃, and Ln(nPr₂,n-hexyl-AMD)_{3.}

A method for forming a lanthanide metal-containing thin film of the present disclosure includes a process of forming a thin film on a substrate using the above precursor for forming the thin film, wherein the process of forming the thin film on the substrate is characterized by including the following processes: forming a precursor thin film through deposition of the precursor for forming the thin film onto a surface of the substrate, and reacting the precursor thin film with a reactant.

Additionally, the process of forming the precursor thin film may include a process of vaporizing the precursor for forming the thin film so as to transfer the resulting vapor of the precursor into a chamber.

Additionally, the deposition may be performed by any one of the following: a spin-on dielectric (SOD) process, a low-temperature plasma (LTP) process, a chemical vapor deposition (CVD) process, a plasma-enhanced CVD (PECVD) process, a high-density plasma CVD (HDPCVD) process, an atomic layer deposition (ALD) process, or a plasma-enhanced ALD (PEALD) process.

Additionally, the process of forming the thin film on the substrate may be performed at a temperature in the range of 150° C. to 500° C.

Additionally, the reactant may include one or more of the following: nitrogen (N₂), ammonia (NH₃), hydrazine (N₂H₄), nitrous oxide (N₂O), oxygen (O₂), water vapor (H₂O), ozone (O₃), hydrogen peroxide (H₂O₂), silane, hydrogen (H), and diborane (B₂H₆).

Additionally, the process of forming the lanthanide metal-containing thin film on the substrate may include a step of feeding the precursor for forming the thin film onto the substrate and applying a plasma, thereby forming the thin film.

Additionally, the lanthanide metal-containing thin film of the present disclosure may be formed using the precursor for forming the thin film, and a semiconductor device of the present disclosure is characterized by including a thin film manufactured by the above method for forming the lanthanide metal-containing thin film.

### Advantageous Effects

A precursor for forming a lanthanide metal-containing thin film, according to the present disclosure, includes cyclopentadienyl and amidinate ligands, so the precursor compound exhibits properties such as excellent structural stability, high volatility, and high heat resistance, resulting in physical properties suitable for use in a lanthanide metal-containing thin-film formation process.

Additionally, a high-quality lanthanide metal-containing thin film can be formed using the precursor, and a semiconductor device including such a lanthanide metal-containing thin film, manufactured by the above method for forming the thin film, can be provided.

### DESCRIPTION OF DRAWINGS

FIG. 1 shows the proton nuclear magnetic resonance (1H-NMR) result of La(iPr₂Me-AMD)₃.

FIG. 2 shows the thermogravimetric analysis (TGA) result of Tb(Et₂nPr-AMD)₃.

FIG. 3 shows the differential scanning calorimetry (DSC) result of Tb(Et₂nPr-AMD)₃.

FIG. 4 shows the TGA result of Dy(Et₂nPr-AMD)₃.

FIG. 5 shows the DSC result of Dy(Et₂nPr-AMD)₃.

FIG. 6 shows the TGA result of Er(Et₂nPr-AMD)₃.

FIG. 7 shows the DSC result of Er(Et₂nPr-AMD)₃.

FIG. 8 shows the TGA result of Yb(Et₂nPr-AMD)₃.

FIG. 9 shows the 1H-NMR result of Lu(Et₂nPr-AMD)₃.

FIG. 10 shows the TGA result of Lu(Et₂nPr-AMD)₃.

FIG. 11 shows the DSC result of Lu(Et₂nPr-AMD)₃.

### MODE FOR INVENTION

Hereinafter, the present disclosure will be described in more detail. All terms or words used in this specification and the appended claims should not be construed as being limited to general and dictionary meanings, but will be interpreted based on the meanings and concepts corresponding to the technical ideas of the present disclosure, following the principle that any inventor is allowed to define the concepts of terms as appropriate to describe the disclosure thereof in the best mode.

A precursor for forming a lanthanide metal-containing thin film, according to the present disclosure, is characterized by including a compound of Chemical Formula 1 below.

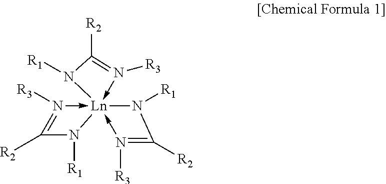

In Chemical Formula 1, Ln refers to a lanthanide metal, R₁ and R₃ are each independently a straight-chain, branched-chain, or cyclic alkyl or alkenyl group having 1 to 5 carbon atoms, and R₂ is a hydrogen atom, or a straight-chain, branched-chain, or cyclic alkyl or alkenyl group having 1 to 8 carbon atoms.

The lanthanide metal refers to 15 elements ranging from the atomic numbers 57, lanthanum (La), to 71, lutetium (Lu), which may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

In the amidinate ligand, R₁ and R₃ may be the same or different.

Additionally, R₂ constituting the amidinate ligand in Chemical Formula 1 may be a hydrogen atom, or a straight-chain, branched-chain, or cyclic alkyl or alkenyl group having 1 to 8 carbon atoms. Preferably, R₂ includes an n-alkyl group, such as an ethyl group, a propyl group, or a butyl group.

The precursor for forming the thin film can form various types of compounds with varying functional groups.

In one embodiment, R₂ in Chemical Formula 1 may be a hydrogen atom, or a straight-chain, branched-chain, or cyclic alkyl or alkenyl group having 1 to 4 carbon atoms.

Additionally, R₁ and R₃ may each independently be a straight-chain, branched-chain, or cyclic alkyl or alkenyl group having 2 to 5 carbon atoms. Alternatively, R₁ and R₃ may be ethyl groups, and R₂ may be an n-propyl group.

Additionally, R₁ and R₃ may each independently be a straight-chain alkyl or alkenyl group having 1 to 5 carbon atoms.

Additionally, in Chemical Formula 1, R₂ may be a straight-chain alkyl or alkenyl group having 1 to 8 carbon atoms.

Additionally, in Chemical Formula 1, R₁ and R₃ may both be the same, and may be straight-chain, branched-chain, or cyclic alkyl or alkenyl groups having 1 to 5 carbon atoms.

Additionally, examples of the compound represented by Chemical Formula 1 constituting the precursor for forming the thin film, as described above, may include the following compounds:
Ln(Me₂,H-AMD)₃, Ln(Me₂,Me-AMD)₃, Ln(Me₂,Et-AMD)₃, Ln(Me₂,nPr-AMD)₃, Ln(Me₂,iPr-AMD)₃, Ln(Me₂,nBu-AMD)₃, Ln(Me₂,isoBu-AMD)₃, Ln(Me₂,secBu-AMD)₃, Ln(Me₂,tertBu-AMD)₃, Ln(Me₂,n-pentyl-AMD)₃, Ln(Me₂,sec-pentyl-AMD)₃, Ln(Me₂,cyclopentyl-AMD)₃, Ln(Me₂,n-hexyl-AMD)₃, Ln(Et,Me,H-AMD)₃, Ln(Et,Me,Me-AMD)₃, Ln(Et,Me,Et-AMD)₃, Ln(Et,Me,nPr-AMD)₃, Ln(Et,Me,iPr-AMD)₃, Ln(Et,Me,nBu-AMD)₃, Ln(Et,Me,isoBu-AMD)₃, Ln(Et,Me,secBu-AMD)₃, Ln(Et,Me,tertBu-AMD)₃, Ln(Et,Me,n-pentyl-AMD)₃, Ln(Et,Me,sec-pentyl-AMD)₃, Ln(Et,Me,cyclopentyl-AMD)₃, Ln(Et,Me,n-hexyl-AMD)₃, Ln(Et₂,H-AMD)₃, Ln(Et₂,Me-AMD)₃, Ln(Et₂,Et-AMD)₃, Ln(Et₂,nPr-AMD)₃, Ln(Et₂,iPr-AMD)₃, Ln(Et₂,nBu-AMD)₃, Ln(Et₂,isoBu-AMD)₃, Ln(Et₂,secBu-AMD)₃, Ln(Et₂,tertBu-AMD)₃, Ln(Et₂,n-pentyl-AMD)₃, Ln(Et₂,sec-pentyl-AMD)₃, Ln(Et₂,cyclopentyl-AMD)₃, Ln(Et₂,n-hexyl-AMD)₃, Ln(Et,nPr,H-AMD)₃, Ln(Et,nPr,Me-AMD)₃, Ln(Et,nPr,Et-AMD)₃, Ln(Et,nPr,nPr-AMD)₃, Ln(Et,nPr,iPr-AMD)₃, Ln(Et,nPr,nBu-AMD)₃, Ln(Et,nPr,isoBu-AMD)₃, Ln(Et,nPr,secBu-AMD)₃, Ln(Et,nPr,tertBu-AMD)₃, Ln(Et,nPr,n-pentyl-AMD)₃, Ln(Et,nPr,sec-pentyl-AMD)₃, Ln(Et,nPr,cyclopentyl-AMD)₃, Ln(Et,nPr,n-hexyl-AMD)₃, Ln(nPr,Me,H-AMD)₃, Ln(nPr,Me,Me-AMD)₃, Ln(nPr,Me,Et-AMD)₃, Ln(nPr,Me,nPr-AMD)₃, Ln(nPr,Me,iPr-AMD)₃, Ln(nPr,Me,nBu-AMD)₃, Ln(nPr,Me,isoBu-AMD)₃, Ln(nPr,Me,secBu-AMD)₃, Ln(nPr,Me,tertBu-AMD)₃, Ln(nPr,Me,n-pentyl-AMD)₃, Ln(nPr,Me,sec-pentyl-AMD)₃, Ln(nPr,Me,cyclopentyl-AMD)₃, Ln(nPr,Me,n-hexyl-AMD)₃, Ln(nPr₂,H-AMD)₃, Ln(nPr₂,Me-AMD)₃, Ln(nPr₂,Et-AMD)₃, Ln(nPr₂,nPr-AMD)₃, Ln(nPr₂,iPr-AMD)₃, Ln(nPr₂,nBu-AMD)₃, Ln(nPr₂,isoBu-AMD)₃, Ln(nPr₂,secBu-AMD)₃, Ln(nPr₂,tertBu-AMD)₃, Ln(nPr₂,n-pentyl-AMD)₃, Ln(nPr₂,sec-pentyl-AMD)₃, Ln(nPr₂,cyclopentyl-AMD)₃, and Ln(nPr₂,n-hexyl-AMD)₃.

The compound represented by Chemical Formula 1 is a precursor containing the amidinate ligand, in which the lanthanide metal serves as a central metal atom. This precursor has high thermal stability and volatility and may be in liquid form at room temperature. Therefore, the chemical properties of a desired precursor can be obtained by synthesizing the precursor containing the ligand.

Specifically, the precursor for forming the thin film may be liquid at room temperature.

Through such a chemical structure of the precursor for forming the thin film, a liquid precursor having high heat resistance and high volatility can be obtained, thereby enabling the formation of a high-quality thin film.

Additionally, the precursor for forming the thin film of the present disclosure may further include a solvent for dissolving or diluting the precursor compound, in consideration of conditions and efficiency of the thin-film formation process. As for the solvent, any one or a mixture of saturated or unsaturated hydrocarbons having 1 to 16 carbon atoms, ketones, ethers, glymes, esters, THF, and tertiary amines may be used. Examples of the saturated or unsaturated hydrocarbons having 1 to 16 carbon atoms may include toluene and heptane, octane, and examples of the tertiary amines may include dimethylethylamine.

In particular, depending on the chemical structure, the precursor compound for forming the thin film may be in a solid form at room temperature. In this case, the compound can be dissolved by involving the solvent. In other words, when involving the solvent, the solvent has a content enabling dissolution of the precursor compound, which is preferably included in an amount in the range of 1 to 99 wt % with respect to the total weight of the precursor for forming the thin film.

The precursors with or without the solvent are vaporizable and thus may be fed into a chamber in the form of precursor gas. Therefore, depending on the types of precursor compounds for forming the thin film, the precursor may be present as a liquid at room temperature and, when being easily vaporizable, the thin-film formation process may be performed even without involving additional solvents.

Additionally, the process of forming the lanthanide metal-containing thin film may be performed by any one of the following: an SOD process, an LTP process, a CVD process, a PECVD process, an HDPCVD process, an ALD process, or a PEALD process.

For example, when being applied, the HDPCVD process may be performed at high vacuum and high power compared to an atmospheric-pressure CVD (APCVD), low-pressure CVD (LPCVD), or PECVD process, thereby enabling the formation of a thin film that is structurally dense and exhibits excellent mechanical properties.

To this end, a method for forming a thin film, according to the present disclosure, includes a process of forming a thin film on a substrate using the above precursor for forming the thin film.

Specifically, the process of forming a lanthanide metal-containing thin film on the substrate may include the following processes: forming a precursor thin film through deposition of the precursor for forming the thin film onto the surface of the substrate, and reacting the precursor thin film with a reactant.

Additionally, for the deposition of the precursor, a process of vaporizing the precursor for forming the thin film so as to transfer the resulting vapor of the precursor into a chamber may be included.

Additionally, the process of forming the lanthanide metal-containing thin film on the substrate may include a process of feeding the precursor for forming the thin film onto the substrate and applying a plasma in the presence of the reactant, thereby forming a metal thin film, an oxide thin film, a nitride thin film, an oxynitride thin film, and the like.

The process of forming the thin film may be performed under an in-chamber pressure in the range of 1 to 1000 mTorr. Additionally, it is suitable that a source power for plasma formation in the chamber is in the range of 500 to 9,000 W, while a bias power is in the range of 0 to 5,000 W. Furthermore, the bias power may not be applied in some cases.

Additionally, the process of forming the thin film on the substrate may be performed at a temperature in the range of 150° C. to 500° C.

Additionally, when feeding the precursor for forming the thin film, a second metal precursor may be introduced, as needed, in order to further improve the electrical properties of a metal film to be ultimately formed, that is, to improve the capacitance or reduce the leakage current value. As for the second metal precursor, a metal precursor containing one or more metals (M″) selected from silicon (Si), titanium (Ti), germanium (Ge), strontium (Sr), niobium (Nb), barium (Ba), hafnium (Hf), tantalum (Ta), and actinide (Ac) atoms may further be optionally fed. The second metal precursor may be an alkoxy-based compound or an alkylamide-based compound containing the metal described above. When the metal is Si, examples of the second metal precursor used may include SiH(N(CH₃)₂)₃, Si(N(C₂H₅)₂)₄, Si(N(C₂H₅)(CH₃))₄, Si(N(CH₃)₂)₄, Si(OC₄H₉)₄, Si(OC₂H₅)₄, Si(OCH₃)₄, and Si(OC(CH₃)₃)₄.

The feeding of the second metal precursor may be performed in the same manner as the feeding of the precursor for forming the thin film. Additionally, the second metal precursor may be fed onto the substrate for forming the thin film in combination with the precursor, or may be fed sequentially after the precursor is completely fed.

Before being fed into the reaction chamber, the precursor for forming the thin film and, optionally, the second metal precursor described above are preferably maintained at a temperature in the range of 50° C. to 250° C. and are more preferably maintained at a temperature in the range of 100° C. to 200° C., so as to make contact with the substrate for forming the thin film.

Additionally, after the step of feeding the precursor and before feeding the reactant, a purge process using an inert gas, such as argon (Ar), nitrogen (N₂), or helium (He), in a reactor may be performed to help the precursor and, optionally, the second metal precursor move onto the substrate or allow for the internal pressure of the reactor suitable for deposition and also to remove impurities from the chamber to the outside. In this case, the purge process using the inert gas is preferably performed so that the internal pressure of the reactor is in the range of 1 to 5 Torr.

Additionally, as for the reactant, one or more of the following may be used: nitrogen (N₂), ammonia (NH₃), hydrazine (N₂H₄), nitrous oxide (N₂O), oxygen (O₂), water vapor (H₂O), ozone (O₃), hydrogen peroxide (H₂O₂), silane, hydrogen (H), and diborane (B₂H₆). When the thin-film formation process is performed in the presence of oxidizing gases such as water vapor, oxygen, and ozone, as described above, a magnesium oxide thin film may be formed. Alternatively, when the thin-film formation process is performed in the presence of reducing gases such as hydrogen, ammonia, hydrazine, and silane, a pure metal thin film or metal nitride thin film may be formed. Additionally, a metal oxynitride thin film may be formed by a mixture of the reactants.

Furthermore, a treatment process through heat treatment or light irradiation may be performed in addition to plasma treatment. This treatment process is configured to provide the heat energy required to deposit the precursor for forming the thin film, and may be performed by known methods. Preferably, to manufacture thin films having the desired physical state and composition at a sufficient growth rate, it is desirable that the above treatment process is performed so that the temperature of the substrate in the reactor is in the range of 100° C. to 1,000° C., preferably in the range of 250° C. to 400° C.

Additionally, even during the above treatment process, a purge process using an inert gas, such as argon (Ar), nitrogen (N₂), or helium (He), in a reactor may be performed to help the reactant move onto the substrate or allow for the internal pressure of the reactor suitable for deposition and also to remove impurities or byproducts from the reactor to the outside, as described above.

The treatment process including the feeding of the precursor for forming the thin film, the feeding of the reactant, and the feeding of the inert gas, as described above, is defined as one cycle, and by repeatedly performing one or more cycles, a thin film can be formed.

Additionally, with the application of the thin-film formation process above, various semiconductor devices including such a thin film may be manufactured.

The following examples are to describe the effects of the present disclosure.

### [Comparative Example 1] Synthesis of tris-(diisopropyl-methylamidinato)lanthanum [La(iPr₂Me-AMD)₃]

To a 500 mL Schlenk flask, 20.0 g (0.0815 mol) of LaCl₃ and 160 mL of THF were added, followed by stirring at room temperature for 4 hours. Subsequently, 80 mL of THF and 155.5 mL (0.2487 mol) of a MeLi-diethyl ether solution (1.6 M) were added to the 500 mL Schlenk flask and then cooled to −78° C., followed by slowly adding 30.86 g (0.2446 mol) of 1,3-diisopropylcarbodiimide dropwise and stirring at room temperature for 6 hours, thereby preparing Li-(iPr₂Me-AMD). The prepared Li-(iPr₂Me-AMD) solution was added dropwise to the flask containing 20.0 g (0.0815 mol) of LaCl₃ at 0° C., followed by stirring at room temperature for 12 hours. The resulting mixture was filtered, followed by evaporation of the solvent and volatiles from the filtrate under vacuum. The unevaporated residues were then distilled at 260° C. and 150 mTorr, thus obtaining a light yellow solid. The yield was 25.1 g (54.7%).

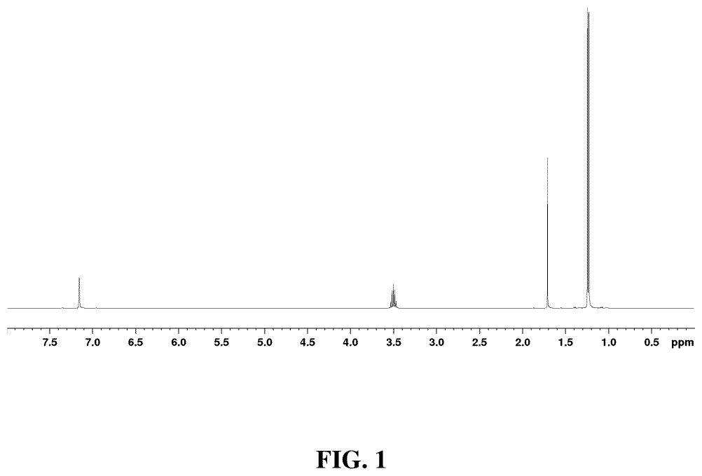

The ¹H-NMR (AV400 MHz HD from Bruker) result shown in FIG. 1 confirmed that a lanthanide metal compound of Chemical Formula 1-1 below was synthesized.

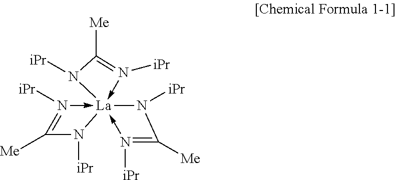

### [Example 1] Synthesis of tris-(diethyl-n-propylamidinato)terbium [Tb(Et₂nPr-AMD)₃]

To a 500 mL Schlenk flask, 10.0 g (0.0377 mol) of TbCl₃ and 50 mL of THF were added, followed by stirring at room temperature for 4 hours. Subsequently, 50 mL of THF and 16.1 g (0.114 mol) of diethyl-n-propylamidinate were added to a 250 mL Schlenk flask and then cooled to −78° C., followed by slowly adding 47.5 mL (0.119 mol) of an n-BuLi-hexane solution (2.5 M) dropwise and stirring at room temperature for 2 hours, thereby preparing Li-(Et₂nPr-AMD). The prepared Li-(Et₂nPr-AMD) solution was added dropwise to the flask containing 10 g (0.0377 mol) of TbCl₃ at 0° C., followed by stirring at room temperature for 6 hours. The resulting mixture was filtered, followed by evaporation of the solvent and volatiles from the filtrate under vacuum. The unevaporated residues were then distilled at 220° C. and 138 m Torr, thus obtaining a yellow liquid. The yield was 11.0 g (50.1%), and the resulting compound was identified as a lanthanide metal compound of Chemical Formula 1-2 below.

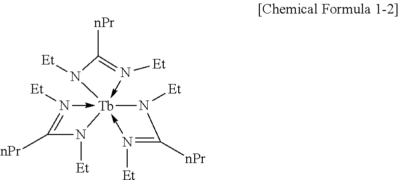

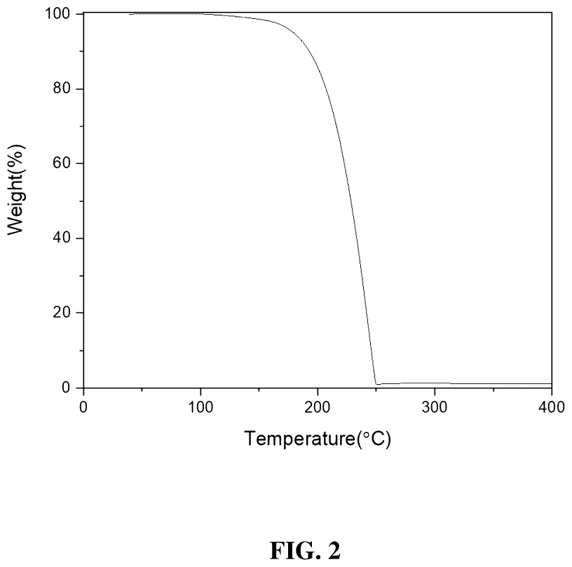

During TGA measurement (SDT Q600 from TA Instruments) performed at a temperature ramp rate of 10° C./min in a nitrogen atmosphere at a flow rate of 200 mL/min, the yellow liquid had a residual mass of 1.18%, indicating that there were almost no residues left. This result was confirmed by the TGA result in FIG. 2, which shows the percentage of weight loss as a function of temperature.

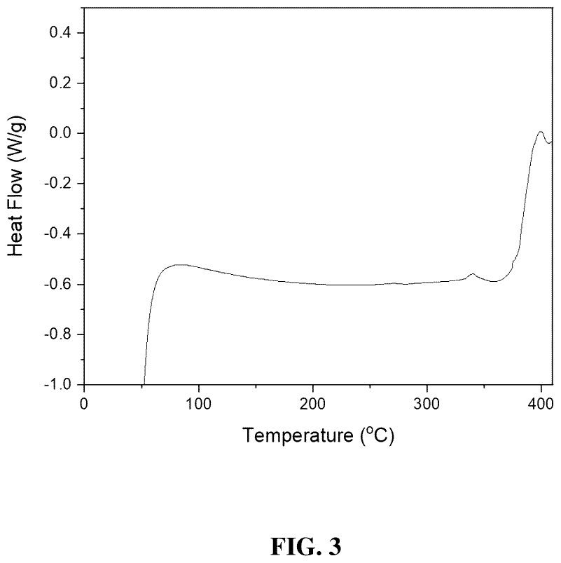

Additionally, the yellow liquid sample was placed in a sealed container for DSC and maintained at 40° C. for 10 minutes. Subsequently, a decomposition peak was observed at 417° C. during DSC measurement (Discovery 25 from TA Instruments) performed at a temperature ramp rate of 10° C./min. This result was confirmed by the DSC result in FIG. 3, which shows the heat energy change as a function of temperature.

### [Example 2] Synthesis of tris-(diethyl-n-propylamidinato)dysprosium [Dy(Et₂nPr-AMD)₃]

To a 500 mL Schlenk flask, 10.0 g (0.0372 mol) of DyCl₃ and 50 mL of THF were added, followed by stirring at room temperature for 4 hours. Subsequently, 50 mL of THF and 15.9 g (0.112 mol) of diethyl-n-propylamidinate were added to a 250 mL Schlenk flask and then cooled to −78° C., followed by slowly adding 46.9 mL (0.117 mol) of an n-BuLi-hexane solution (2.5 M) dropwise and stirring at room temperature for 2 hours, thereby preparing Li-(Et₂nPr-AMD). The prepared Li-(Et₂nPr-AMD) solution was added dropwise to the flask containing 10 g (0.0372 mol) of DyCl₃ at 0° C., followed by stirring at room temperature for 6 hours. The resulting mixture was filtered, followed by evaporation of the solvent and volatiles from the filtrate under vacuum. The unevaporated residues were then distilled at 220° C. and 90 mTorr, thus obtaining a yellow liquid. The yield was 13.8 g (69%), and the resulting compound was identified as a lanthanide metal compound of Chemical Formula 1-3 below.

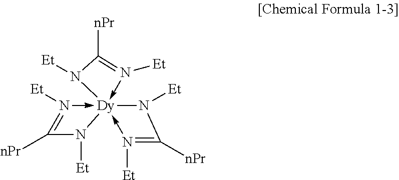

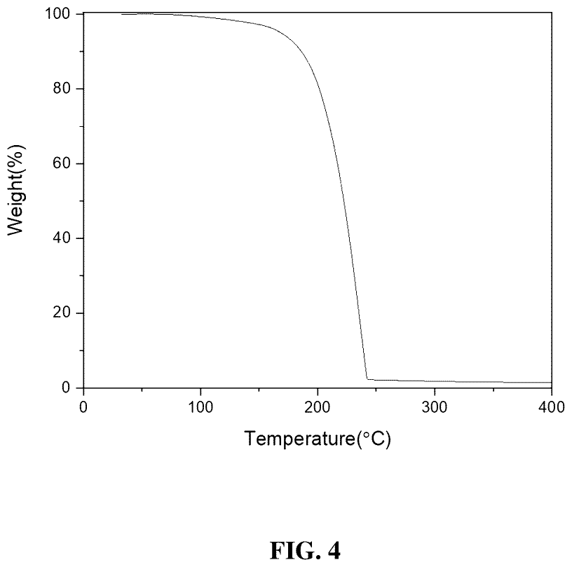

During TGA measurement (SDT Q600 from TA Instruments) performed at a temperature ramp rate of 10° C./min in a nitrogen atmosphere at a flow rate of 200 mL/min, the yellow liquid had a residual mass of 1.59%, indicating that there were almost no residues left. This result was confirmed by the TGA result in FIG. 4, which shows the percentage of weight loss as a function of temperature.

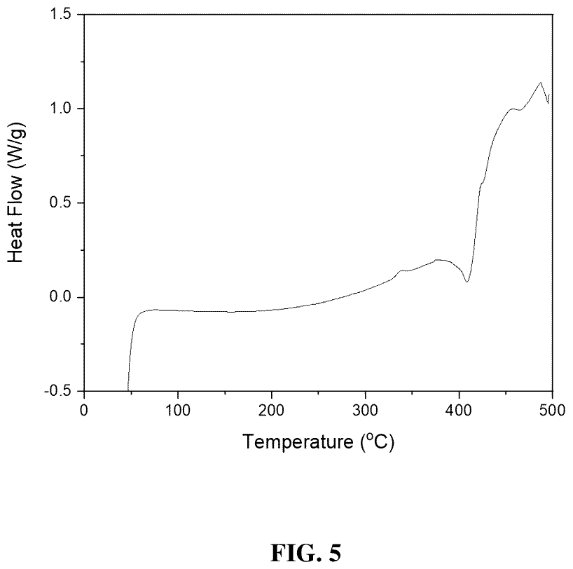

Additionally, the yellow liquid sample was placed in a sealed container for DSC and maintained at 40° C. for 10 minutes. Subsequently, a decomposition peak was observed at 487° C. during DSC measurement (Discovery 25 from TA Instruments) performed at a temperature ramp rate of 10° C./min. This result was confirmed by the DSC result in FIG. 5, which shows the heat energy change as a function of temperature.

### [Example 3] Synthesis of tris-(diethyl-n-propylamidinato)erbium [Er(Et₂nPr-AMD)₃]

To a 500 mL Schlenk flask, 10.0 g (0.0365 mol) of ErCl₃ and 50 mL of THF were added, followed by stirring at room temperature for 4 hours. Subsequently, 50 mL of THF and 15.6 g (0.110 mol) of diethyl-n-propylamidinate were added to a 250 mL Schlenk flask and then cooled to −78° C., followed by slowly adding 46.0 mL (0.115 mol) of an n-BuLi-hexane solution (2.5 M) dropwise and stirring at room temperature for 2 hours, thereby preparing Li-(Et₂nPr-AMD). The prepared Li-(Et₂nPr-AMD) solution was added dropwise to the flask containing 10 g (0.0365 mol) of ErCl₃ at 0° C., followed by stirring at room temperature for 6 hours. The resulting mixture was filtered, followed by evaporation of the solvent and volatiles from the filtrate under vacuum. The unevaporated residues were then distilled at 220° C. and 80 mTorr, thus obtaining an orange liquid. The yield was 14 g (72%), and the resulting compound was identified as a lanthanide metal compound of Chemical Formula 1-4 below.

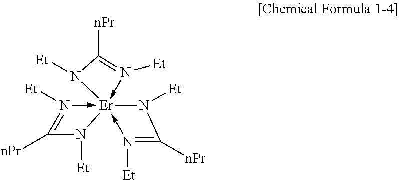

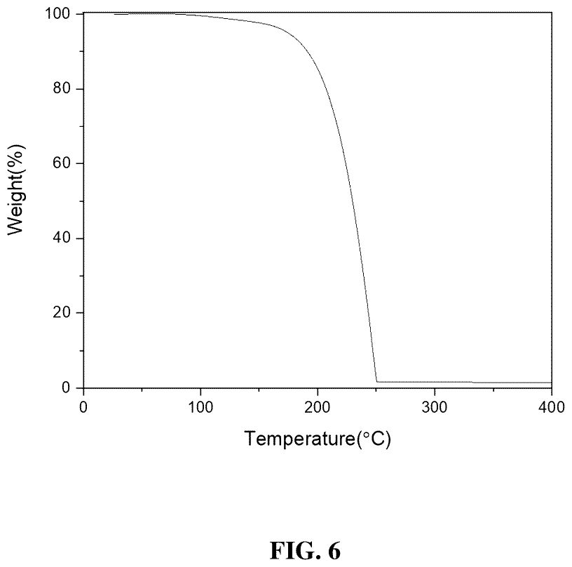

During TGA measurement (SDT Q600 from TA Instruments) performed at a temperature ramp rate of 10° C./min in a nitrogen atmosphere at a flow rate of 200 mL/min, the orange liquid had a residual mass of 1.52%, indicating that there were almost no residues left. This result was confirmed by the TGA result in FIG. 6, which shows the percentage of weight loss as a function of temperature.

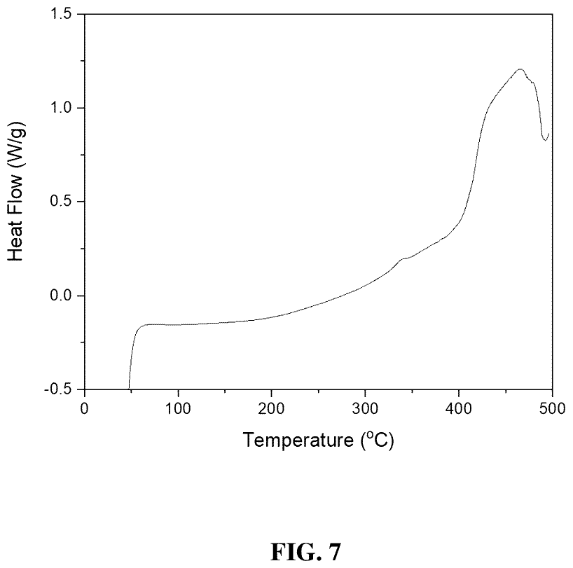

Additionally, the orange liquid sample was placed in a sealed container for DSC and maintained at 40° C. for 10 minutes. Subsequently, a decomposition peak was observed at 466° C. during DSC measurement (Discovery 25 from TA Instruments) performed at a temperature ramp rate of 10° C./min. This result was confirmed by the DSC result in FIG. 7, which shows the heat energy change as a function of temperature.

To further examine the viscosity of the orange liquid, this sample was placed in a measurement container of a rotational viscometer (LVD2T from Brookfield) for viscosity measurement at 25° C. using a low-viscosity spindle. The viscosity was found to be 77.1 cPs.

### [Example 4] Synthesis of tris-(diethyl-n-propylamidinato)ytterbium [Yb(Et₂nPr-AMD)₃]

Toa 500 mL Schlenk flask, 10.0 g (0.0358 mol) of YbCl₃ and 50 mL of THF were added, followed by stirring at room temperature for 4 hours. Subsequently, 50 mL of THF and 15.3 g (0.107 mol) of diethyl-n-propylamidinate were added to a 250 mL Schlenk flask and then cooled to −78° C., followed by slowly adding 45.1 mL (0.113 mol) of an n-BuLi-hexane solution (2.5 M) dropwise and stirring at room temperature for 2 hours, thereby preparing Li-(Et₂nPr-AMD). The prepared Li-(Et₂nPr-AMD) solution was added dropwise to the flask containing 10 g (0.0358 mol) of YbCl₃ at 0° C., followed by stirring at room temperature for 6 hours. The resulting mixture was filtered, followed by evaporation of the solvent and volatiles from the filtrate under vacuum. The unevaporated residues were then distilled at 220° C. and 68 mTorr, thus obtaining a yellow liquid. The yield was 14 g (70%), and the resulting compound was identified as a lanthanide metal compound of Chemical Formula 1-5 below.

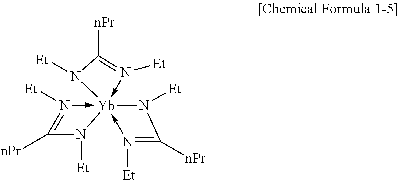

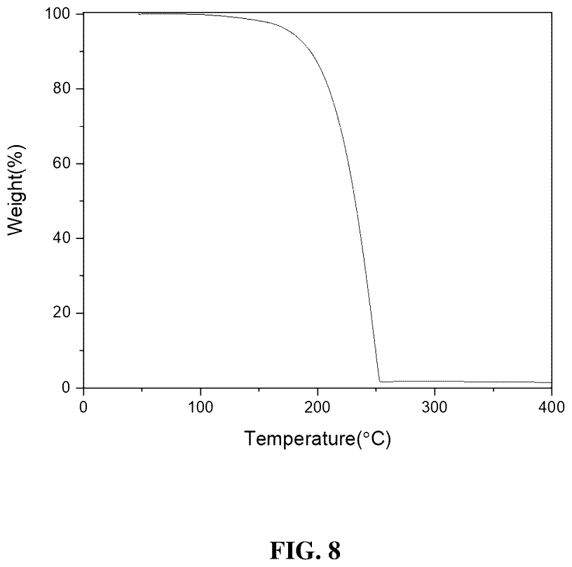

During TGA measurement (SDT Q600 from TA Instruments) performed at a temperature ramp rate of 10° C./min in a nitrogen atmosphere at a flow rate of 200 mL/min, the yellow liquid had a residual mass of 1.68%, indicating that there were almost no residues left. This result was confirmed by the TGA result in FIG. 8, which shows the percentage of weight loss as a function of temperature.

To further examine the viscosity of the yellow liquid, this sample was placed in a measurement container of a rotational viscometer (LVD2T from Brookfield) for viscosity measurement at 25° C. using a low-viscosity spindle. The viscosity was found to be 66.2 cPs.

### [Example 5] Synthesis of tris-(diethyl-n-propylamidinato)lutetium [Lu(Et₂nPr-AMD)₃]

To a 500 mL Schlenk flask, 10.0 g (0.0355 mol) of LuCl₃ and 50 mL of THF were added, followed by stirring at room temperature for 4 hours. Subsequently, 50 mL of THF and 15.2 g (0.107 mol) of diethyl-n-propylamidinate were added to a 250 mL Schlenk flask and then cooled to −78° C., followed by slowly adding 44.8 mL (0.112 mol) of an n-BuLi-hexane solution (2.5 M) dropwise and stirring at room temperature for 2 hours, thereby preparing Li-(Et₂nPr-AMD). The prepared Li-(Et₂nPr-AMD) solution was added dropwise to the flask containing 10 g (0.0355 mol) of LuCl₃ at 0° C., followed by stirring at room temperature for 6 hours. The resulting mixture was filtered, followed by evaporation of the solvent and volatiles from the filtrate under vacuum. The unevaporated residues were then distilled at 220° C. and 54 mTorr, thus obtaining an orange liquid. The yield was 16.2 g (75.8%).

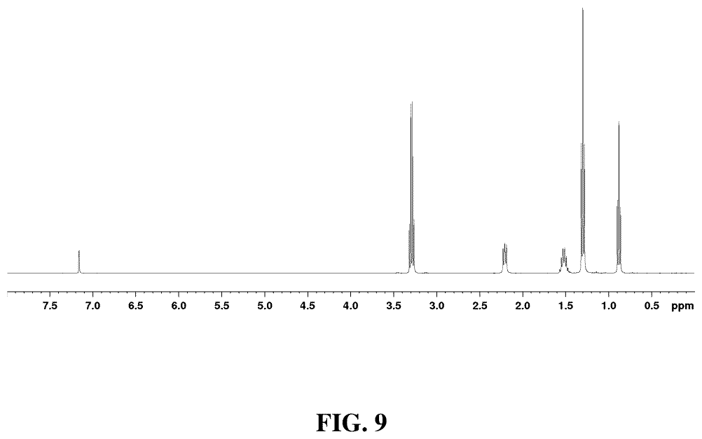

The ¹H-NMR (AV400 MHz HD from Bruker) result of the above compound is as shown in FIG. 9, and the characteristic peaks observed at 0.88 (t, 9H), 1.30 (t, 18H), 1.51 (q, 6H), 2.21 (q, 6H), and 3.28 (q, 12H) confirm the synthesis of a lanthanide metal compound of Chemical Formula 1-6 below.

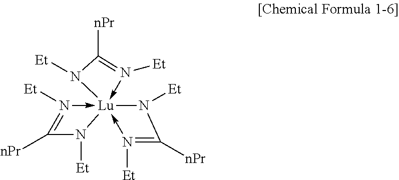

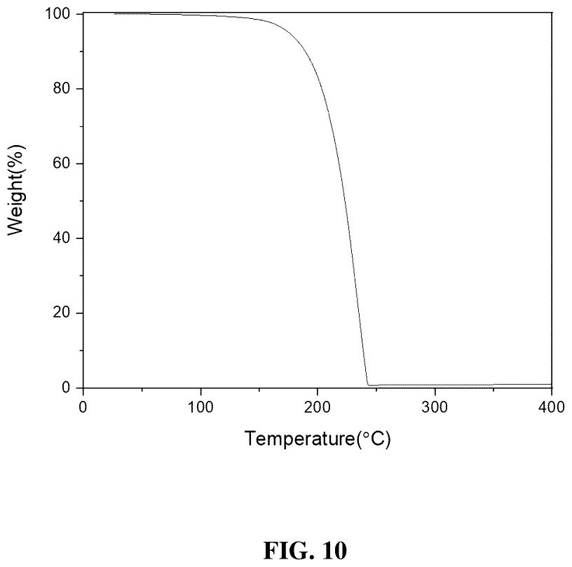

During TGA measurement (SDT Q600 from TA Instruments) performed at a temperature ramp rate of 10° C./min in a nitrogen atmosphere at a flow rate of 200 mL/min, the orange liquid had a residual mass of 0.95%, indicating that there were almost no residues left. This result was confirmed by the TGA result in FIG. 10, which shows the percentage of weight loss as a function of temperature.

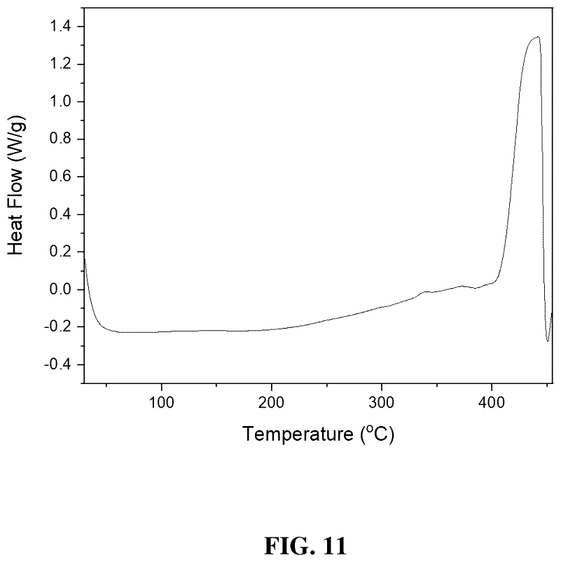

Additionally, the orange liquid sample was placed in a sealed container for DSC and maintained at 40° C. for 10 minutes. Subsequently, a decomposition peak was observed at 442° C. during DSC measurement (Discovery 25 from TA Instruments) performed at a temperature ramp rate of 10° C./min. This result was confirmed by the DSC result in FIG. 11, which shows the heat energy change as a function of temperature.

The present disclosure has been described hereinabove with reference to preferred embodiments, but is not limited to these embodiments. Various modifications and changes may be made by those skilled in the art to which the present disclosure belongs without departing from the idea of the present disclosure. Such modifications and changes should be construed as falling within the scope of the present disclosure and the appended claims.

1. A precursor for forming a lanthanide metal-containing thin film, the precursor comprising a lanthanide metal-containing compound represented by Chemical Formula 1 below, 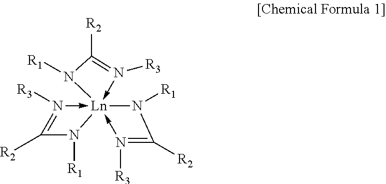
wherein in Chemical Formula 1,
Ln refers to a lanthanide metal, R₁ and R₅ are each independently a straight-chain, branched-chain, or cyclic alkyl or alkenyl group having 1 to 5 carbon atoms, and R₂ is a hydrogen atom, or a straight-chain, branched-chain, or cyclic alkyl or alkenyl group having 1 to 8 carbon atoms.

2. The precursor of claim 1, wherein in Chemical Formula 1, R₂ is a hydrogen atom, or a straight-chain, branched-chain, or cyclic alkyl or alkenyl group having 1 to 4 carbon atoms.

3. The precursor of claim 1, wherein in Chemical Formula 1, R₁ and R₃ are each independently a straight-chain, branched-chain, or cyclic alkyl or alkenyl group having 2 to 5 carbon atoms.

4. The precursor of claim 1, wherein in Chemical Formula 1, R₁ and R₃ are ethyl groups.

5. The precursor of claim 1, wherein in Chemical Formula 1, R₂ is an n-propyl group.

6. The precursor of claim 1, wherein in Chemical Formula 1, R₁ and R₃ are each independently a straight-chain alkyl or alkenyl group having 1 to 5 carbon atoms.

7. The precursor of claim 1, wherein in Chemical Formula 1, R₂ is a straight-chain alkyl or alkenyl group having 1 to 8 carbon atoms.

8. The precursor of claim 1, wherein in Chemical Formula 1, R₁ and R₃ are both the same, and are straight-chain, branched-chain, or cyclic alkyl or alkenyl groups having 1 to 5 carbon atoms.

9. The precursor of claim 1, wherein the precursor is liquid at room temperature.

10. The precursor of claim 1, further comprising a solvent.

11. The precursor of claim 10, wherein the solvent comprises one or more of the following: a saturated or unsaturated hydrocarbon having 1 to 16 carbon atoms, a ketone, an ether, glyme, an ester, tetrahydrofuran, and a tertiary amine.

12. The precursor of claim 10, wherein the solvent is included in an amount in a range of 1 to 99 wt % with respect to the total weight of the precursor.

13. The precursor of claim 1, wherein the lanthanide metal-containing compound represented by Chemical Formula 1 comprises at least one selected from the following compounds:
Ln(Me₂,H-AMD)₃, Ln(Me₂,Me-AMD)₃, Ln(Me₂,Et-AMD)₃, Ln(Me₂,nPr-AMD)₃, Ln(Me₂,iPr-AMD)₃, Ln(Me₂,nBu-AMD)₃, Ln(Me₂,isoBu-AMD)₃, Ln(Me₂,secBu-AMD)₃, Ln(Me₂,tertBu-AMD)₃, Ln(Me₂,n-pentyl-AMD)₃, Ln(Me₂,sec-pentyl-AMD)₃, Ln(Me₂,cyclopentyl-AMD)₃, Ln(Me₂,n-hexyl-AMD)₃, Ln(Et,Me,H-AMD)₃, Ln(Et,Me,Me-AMD)₃, Ln(Et,Me,Et-AMD)₃, Ln(Et,Me,nPr-AMD)₃, Ln(Et,Me,iPr-AMD)₃, Ln(Et,Me,nBu-AMD)₃, Ln(Et,Me,isoBu-AMD)₃, Ln(Et,Me,secBu-AMD)₃, Ln(Et,Me,tertBu-AMD)₃, Ln(Et,Me,n-pentyl-AMD)₃, Ln(Et,Me,sec-pentyl-AMD)₃, Ln(Et,Me,cyclopentyl-AMD)₃, Ln(Et,Me,n-hexyl-AMD)₃, Ln(Et₂,H-AMD)₃, Ln(Et₂,Me-AMD)₃, Ln(Et₂,Et-AMD)₃, Ln(Et₂,nPr-AMD)₃, Ln(Et₂,iPr-AMD)₃, Ln(Et₂,nBu-AMD)₃, Ln(Et₂,isoBu-AMD)₃, Ln(Et₂,secBu-AMD)₃, Ln(Et₂,tertBu-AMD)₃, Ln(Et₂,n-pentyl-AMD)₃, Ln(Et₂, sec-pentyl-AMD)₃, Ln(Et₂,cyclopentyl-AMD)₃, Ln(Et₂,n-hexyl-AMD)₃, Ln(Et,nPr,H-AMD)₃, Ln(Et,nPr,Me-AMD)₃, Ln(Et,nPr,Et-AMD)₃, Ln(Et,nPr,nPr-AMD)₃, Ln(Et,nPr,iPr-AMD)₃, Ln(Et,nPr,nBu-AMD)₃, Ln(Et,nPr,isoBu-AMD)₃, Ln(Et,nPr,secBu-AMD)₃, Ln(Et,nPr,tertBu-AMD)₃, Ln(Et,nPr,n-pentyl-AMD)₃, Ln(Et,nPr,sec-pentyl-AMD)₃, Ln(Et,nPr,cyclopentyl-AMD)₃, Ln(Et,nPr,n-hexyl-AMD)₃, Ln(nPr,Me,H-AMD)₃, Ln(nPr,Me,Me-AMD)₃, Ln(nPr,Me,Et-AMD)₃, Ln(nPr,Me,nPr-AMD)₃, Ln(nPr,Me,iPr-AMD)₃, Ln(nPr,Me,nBu-AMD)₃, Ln(nPr,Me,isoBu-AMD)₃, Ln(nPr,Me,secBu-AMD)₃, Ln(nPr,Me,tertBu-AMD)₃, Ln(nPr,Me,n-pentyl-AMD)₃, Ln(nPr,Me,sec-pentyl-AMD)₃, Ln(nPr,Me,cyclopentyl-AMD)₃, Ln(nPr,Me,n-hexyl-AMD)₃, Ln(nPr₂,H-AMD)₃, Ln(nPr₂,Me-AMD)₃, Ln(nPr₂,Et-AMD)₃, Ln(nPr₂,nPr-AMD)₃, Ln(nPr₂,iPr-AMD)₃, Ln(nPr₂,nBu-AMD)₃, Ln(nPr₂,isoBu-AMD)₃, Ln(nPr₂,secBu-AMD)₃, Ln(nPr₂, tertBu-AMD)₃, Ln(nPr₂,n-pentyl-AMD)₃, Ln(nPr₂,sec-pentyl-AMD)₃, Ln(nPr₂,cyclopentyl-AMD)₃, and Ln(nPr₂,n-hexyl-AMD)₃.

14. A method for forming a lanthanide metal-containing thin film, the method comprising forming a thin film on a substrate using the precursor of claim 1.

15. The method of claim 14, wherein the forming of the thin film on the substrate comprises:
forming a precursor thin film through deposition of the precursor onto a surface of the substrate; and
reacting the precursor thin film with a reactive gas.

16. The method of claim 15, wherein the forming of the precursor thin film comprises vaporizing the precursor so as to transfer the resulting vapor of the precursor into a chamber.

17. The method of claim 15, wherein the deposition is performed by any one of the following: a spin-on dielectric (SOD) process, a low-temperature plasma (LTP) process, a chemical vapor deposition (CVD) process, a plasma-enhanced CVD (PECVD) process, a high-density plasma CVD (HDPCVD) process, an atomic layer deposition (ALD) process, or a plasma-enhanced ALD (PEALD) process.

18. The method of claim 14, wherein the forming of the thin film on the substrate comprises feeding the precursor onto the substrate and applying a plasma, thereby forming the thin film.

19. A semiconductor device comprising a lanthanide metal-containing thin film manufactured by the method of claim 14.
